(19) United States
(12) Patent Application Publication
(10) Pub. No.: US 2008/0006864 A1
(43) Pub. Date: Jan. 10, 2008

(54) Semiconductor device and a manufacturing method thereof

(75) Inventor: Shintaro Arai, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kanagawa (JP)

(21) Appl. No.: 11/822,236

(22) Filed: Jul. 3, 2007

(30) Foreign Application Priority Data
Jul. 6, 2006 (JP) 186311/2006

(51) Int. Cl. H01L 29/94

(52) U.S. Cl. 257/296

(57) ABSTRACT

In a semiconductor device where a memory region and a logic region are embedded, the machining accuracy of the element in the logic region can be maintained well and junction leak can be prevented at an isolation dielectric film part in the memory region. A semiconductor device includes a semiconductor substrate where a DRAM part and a Logic part are embedded and the surface heights of the DRAM part and the Logic part are formed to be almost equal, a first STI film formed in the Logic region of the semiconductor substrate, and a second STI film which is formed in the DRAM part of the semiconductor substrate and has a surface height higher than the surface height of the semiconductor substrate. The difference between the surface height of the first STI film and the surface height of the semiconductor substrate is smaller than the difference between the surface height of the second STI film and the surface height of the semiconductor substrate. The surface height of the first STI film is preferably almost equal to the surface height of the semiconductor substrate.

### BACKGROUND OF THE INVENTION

1. Field of the Invention

The present invention relates to a semiconductor device and a manufacturing method thereof.

2. Description of Related Art

In a semiconductor device in which a memory region and a logic region are embedded, junction leaks become a problem at the STI film parts of the memory region. FIG. 7 is a drawing illustrating a mechanism where a junction leak occurs at the STI film part. The semiconductor device 10 includes a semiconductor substrate 2, an impurity diffusion region 6 and an STI film 54 formed over the surface of the semiconductor substrate 2. Herein, a silicide film 11 is formed over the surface of the impurity diffusion region 6. When the height of the upper face of the STI film 54 is lower than the height of the upper face of the impurity diffusion region 6 (semiconductor substrate 2) in the semiconductor device 10 with such a configuration, a corner of the impurity diffusion region 6 is exposed in the region between the impurity diffusion region 6 and the STI film 54. When the surface of the impurity diffusion region 6 is silicidized in such a condition, the silicide film 11 penetrates toward the lower position at the contact surface with the STI film 54. Therefore, at this part, the distance between the silicide film 11 and the semiconductor substrate 2 becomes smaller, and as indicated by the arrow in the figure, current leakage from the silicide film 11 to the semiconductor substrate 2 occurs easily. When the contact is formed over the silicide film 11, a current leakage from the contact to the semiconductor substrate 2 occurs.

FIG. 8 is a drawing illustrating a mechanism where a junction leak occurs at an STI film part even when it is a structure where the silicide film 11 is not formed. Even in this case, if the corner of the impurity diffusion region 6 (semiconductor substrate 2) is exposed, the contact 14 penetrates between the STI film 54 and the impurity diffusion region 6 when the contact 14 is formed over the impurity diffusion region 6. Therefore, at this part, the distance between the contact 14 and the semiconductor substrate 2 becomes smaller, and as indicated by the arrow in the figure, current leakage from the contact 14 to the semiconductor substrate 2 easily occurs.

Specifically, when the contact connected to the capacitor of a DRAM is formed in the vicinity of the STI film, the charge stored in the capacitor leaks while current leakage occurs as explained in FIGS. 7 and 8, resulting in the hold characteristics of a DRAM being deteriorated.

JP-A No. 2001-85683 describes a technology for preventing such a junction leakage from being generated. The patent document describes a configuration in which a protection film composed of SiN, etc. is formed over the STI film in order to prevent sections of the STI film from being etched in subsequent processing and to do away with sinking of the STI film.

JP-A No. 11 (1999)-3982 describes a configuration in which a memory cell region and a peripheral circuit are provided in a semiconductor substrate in a flash embedded logic LSI with a built-in memory cell, and the height of the upper face of a semiconductor substrate in a second active region formed in the peripheral circuit region is higher than the height of the upper face of the semiconductor substrate in a first active region formed in the peripheral circuit region and is almost equal to the height of the upper face of a floating gate electrode. Therefore, it is said that the upper face of the floating gate electrode and the upper face of the semiconductor substrate in the second active region of the peripheral circuit region is planarized and the flatness of the entire semiconductor device can be maintained excellent.

However, in the technology described in JP-A No. 2001-85683, it is necessary that there be a step for forming a protection film such as an SiN film, etc. and a step for selectively leaving the protection film over the STI film, so that there has been a problem that the procedure becomes complex. Moreover, the present inventor has now discovered that a junction leak as had been mentioned does not become a problem in the logic part compared with the memory part; on the other hand, that the flatness of the element formation region in the logic part is required for obtaining the machining accuracy because an element such as a gate electrode of a transistor formed in the logic region is minute.

Moreover, in the technology described in JP-A No. 11 (1999)-3982, the surface heights of the semiconductor substrate are different in the memory region and the logic region. Therefore, when the same element, for instance, a gate etc. of a transistor is formed in the same step in the memory region and the logic region, the difference of the surface heights thereof creates a problem in that it cannot be accurately formed.

### SUMMARY

According to an embodiment of this invention, there is provided a semiconductor device, which includes

a semiconductor substrate where a memory region and a logic region are embedded,

a first isolation dielectric film formed in the logic region of the semiconductor substrate, and

a second isolation dielectric film formed in the memory region of the semiconductor substrate, the surface height thereof being higher than the surface height of the semiconductor substrate,

in which the surface height of the semiconductor substrate in the logic region and the surface height of the semiconductor substrate in the memory region are almost equal, and

the difference between the surface height of the first isolation dielectric film and the surface height of the semiconductor substrate is smaller than the difference between the surface height of the second isolation dielectric film and the surface height of the semiconductor substrate.

The first and second isolation dielectric films can be composed of an STI (Shallow Trench Isolation) film.

Herein, it is not necessary that the surface height of the second isolation dielectric film be higher than the surface height of the semiconductor substrate in whole area where the isolation dielectric film is formed and there may be a part of region which has a height almost equal to the surface height of the semiconductor substrate. For instance, in the part where the second isolation dielectric film is adjacent to the semiconductor substrate, the surface height thereof may almost be equal to the surface height of the semiconductor substrate. In the semiconductor device of the present invention, when the second isolation dielectric film is formed, the surface height of the second isolation dielectric film can be made higher than the surface height of the semiconductor substrate over whole area where the isolation dielectric film is formed. In the step after forming the second isolation dielectric film, there is a possibility that the second isolation dielectric film is partially removed by being etched, etc. However, even in this case, the surface height of the second isolation dielectric film in the part where the second isolation dielectric film is adjacent to the semiconductor substrate becomes almost equal to or higher than the surface height of the semiconductor substrate in the semiconductor device of the present invention. The surface height of the first isolation dielectric film is formed to be lower than the surface height of the second isolation dielectric film.

In such a configuration, since the surface height of the second isolation dielectric film is higher than the surface height of the semiconductor substrate in the memory region, exposure of a corner of the semiconductor substrate can be prevented even if the upper part of the second isolation dielectric film is partially removed by being etched in a part where the second isolation dielectric film is adjacent to the semiconductor substrate. As a result, junction leakage as explained with reference to FIGS. 7 and 8 can be prevented.

On the other hand, in the logic region, the difference between the surface height of the semiconductor substrate and the surface height of the isolation dielectric film can be made smaller compared with the memory region. Herein, a configuration can be allowed in which the difference between the highest part of the first isolation dielectric film and the surface height of the semiconductor substrate is smaller than the difference between the height of the highest part of the second isolation dielectric film and the surface height of the semiconductor substrate. The surface height of the first isolation dielectric film can be made almost equal to the surface height of the semiconductor substrate. Therefore, the flatness of the element formation region can be maintained and the machining accuracy can be well maintained even if a minute element is formed. Moreover, the surface heights of the semiconductor substrate can be made equal in the memory region and the logic region. Therefore, the machining accuracy can be well maintained when the same element is made in the same step in the memory region and the logic region.

In a semiconductor device of the present invention, a configuration is allowed in which a DRAM (Dynamic Random Access Memory) is formed in the memory region. A semiconductor device of the present invention can include an impurity diffusion region formed in a region adjacent to the second isolation dielectric film at the surface part of the semiconductor substrate, a contact which is provided over the semiconductor and connected electrically to the impurity diffusion region, and a capacitor which is provided over the semiconductor substrate and connected to the contact in the memory region. When junction leakage occurs in such a configuration, charges stored in the capacitor leak, resulting in the hold characteristics thereof being deteriorated. According to a semiconductor device of the present invention, such a junction leakage can be prevented and the hold characteristics can be maintained well.

According to an embodiment of the present invention, a manufacturing method of a semiconductor device is provided, which includes the steps of:

forming a first mask layer over the entire surface of a semiconductor substrate where a memory region and a logic region are embedded,

forming a concave part in the first mask layer and the semiconductor substrate in order to form an isolation dielectric region in the semiconductor substrate in the memory region and the logic region,

forming an insulation film over the entire semiconductor substrate to bury the concave part with the insulation film,

removing the insulation film exposing the outside of the concave part of the first mask layer and forming a first isolation dielectric film and a second isolation dielectric film in the logic region and the memory region, respectively,

forming a second mask layer selectively over the memory region,

removing the upper part of the first isolation dielectric film partially by using the second mask layer as a mask,

removing the second mask layer, and

removing the first mask layer,

in which the surface height of the first isolation dielectric film is made almost equal to the surface height of the semiconductor substrate and the surface height of the second isolation dielectric film is made higher than the surface height of the semiconductor substrate.

According to an embodiment of the present invention, there is provided a semiconductor device, which includes

a semiconductor substrate including first and second regions, surfaces of the first and second regions being the substantially same in height as each other,

a first isolation film selectively formed in the first region, and

a second isolation film selectively formed in the second region,

the first isolation film protruding from the surface of the first region larger than the second isolation film.

One in which each of these configurations is arbitrarily combined and in which the methods, devices, etc. are interchanged to express the invention is also effective as a mode of the present invention.

According to the present invention, in a semiconductor device where a memory region and a logic region are embedded, the machining accuracy can be maintained well in the logic region and junction leak can be prevented from the isolation dielectric part of the memory region.

### BRIEF DESCRIPTION OF THE DRAWINGS

FIG. 1 is a cross-sectional drawing illustrating a configuration of a semiconductor device in an embodiment of the present invention;

FIG. 2 is a cross-sectional drawing illustrating a configuration of a DRAM of a semiconductor device in an embodiment of the present invention;

FIG. 3A is a process cross-sectional drawing illustrating a manufacturing procedure of a semiconductor device in an embodiment of the present invention;

FIG. 3B is a process cross-sectional drawing illustrating a manufacturing procedure of a semiconductor device in an embodiment of the present invention;

FIG. 3C is a process cross-sectional drawing illustrating a manufacturing procedure of a semiconductor device in an embodiment of the present invention;

FIG. 3D is a process cross-sectional drawing illustrating a manufacturing procedure of a semiconductor device in an embodiment of the present invention;

FIG. 4A is a process cross-sectional drawing illustrating a manufacturing procedure of a semiconductor device in an embodiment of the present invention;

FIG. 4B is a process cross-sectional drawing illustrating a manufacturing procedure of a semiconductor device in an embodiment of the present invention;

FIG. 4C is a process cross-sectional drawing illustrating a manufacturing procedure of a semiconductor device in an embodiment of the present invention;

FIG. 5 is a process cross-sectional drawing illustrating a manufacturing procedure of a semiconductor device in an embodiment of the present invention;

FIG. 6 is a top view illustrating a configuration of the semiconductor device in an embodiment of the present invention;

FIG. 7 is a drawing illustrating a mechanism of current leakage generated in the STI film part of the DRAM part; and

FIG. 8 is a drawing illustrating a mechanism of current leakage generated in the STI film part of the DRAM part.

### DETAILED DESCRIPTION OF THE PREFERRED EMBODIMENTS

Hereinafter, embodiments of the present invention will be explained referring to the figures. In all the figures, a similar code is used for a similar component and an explanation is appropriately omitted.

Those skilled in the art will recognize that many alternative embodiments can be accomplished using the teachings of the present invention and that the invention is not limited to the embodiments illustrated for explanatory purposes.

### First Embodiment

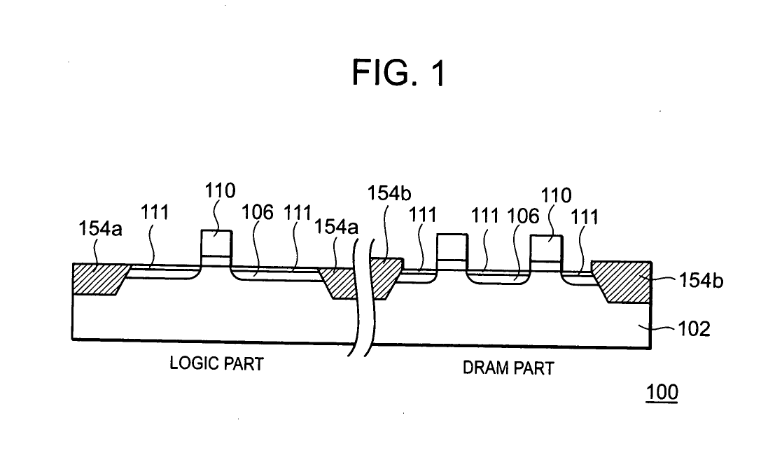

FIG. 1 is a cross-sectional drawing illustrating a semiconductor device 100 of the present invention.

The semiconductor device 100 includes a semiconductor substrate 102 where a DRAM which is a memory region and a Logic part which is a logic region are embedded, and the surface heights of the DRAM part and the Logic part are made almost equal. The semiconductor substrate 102 is, for instance, a silicon substrate.

A second STI film 154b (second isolation dielectric film) a gate 110, and an impurity diffusion layer 106 are formed in the DRAM part of the semiconductor device 100. The impurity diffusion layer 106 is provided connected to the second STI film 154b. The first STI film 154a (first isolation dielectric film), the gate 110, and the impurity diffusion layer 106 are formed in the Logic part of the semiconductor device 100. The impurity diffusion layer 106 is provided adjacent to the first STI film 154a. A silicide film 111 is formed over the surface of the impurity diffusion layer 106 in the Logic part and the DRAM part. Moreover, in the Logic part and the DRAM part, a transistor is composed of the gate 110 and the impurity diffusion layer 106.

In this embodiment, the surface height of the second STI film 154b formed in the DRAM part is formed to be higher than the surface height of the semiconductor substrate 102. On the other hand, the surface height of the first STI film 154a formed in the Logic part is formed to be almost equal to the surface height of the semiconductor substrate 102.

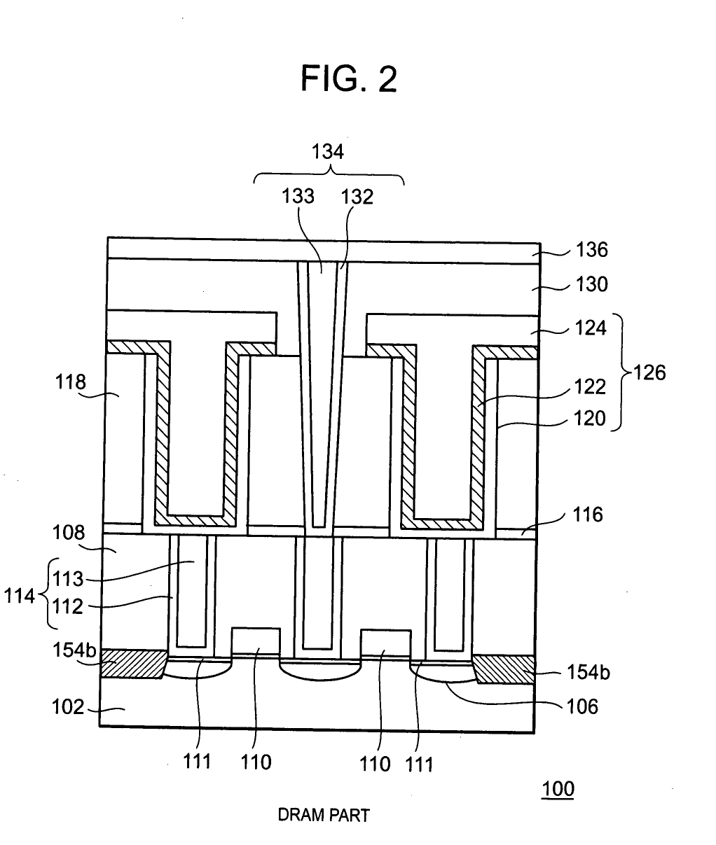

FIG. 2 is a cross-sectional drawing illustrating a configuration of a semiconductor substrate where a capacitor 126 is formed in the DRAM part.

The semiconductor device 100 includes a contact 114 electrically connected to the impurity diffusion layer 106 provided adjacent to the second STI film 154b and a capacitor 126 connected to the contact 114. The contact 114 is electrically connected to the impurity diffusion layer 106 through the silicide film 111. The semiconductor device 100 includes an interlayer dielectric film 108 formed over the semiconductor substrate 102, an etching inhibition film 116 formed over the interlayer dielectric film 108, an interlayer dielectric film 118 formed over the etching inhibition film 116, an interlayer dielectric film 130 formed over the interlayer dielectric film 118, and an interconnection layer 136 formed over the interlayer dielectric film 130. The contact 114 is provided in the interlayer dielectric film 108 and is composed of a barrier metal film 112 and a metallic film 113. The capacitor 126 is provided in the interlayer dielectric film 118 and is composed of a lower electrode 120, a capacitive film 122, and an upper electrode 124.

Moreover, the semiconductor device 100 further includes a contact 134 electrically connected to the impurity diffusion layer 106 provided between the two gates 110. The contact 134 includes a barrier metal film 132 and a metallic film 133. The contact 134 is connected to an interconnection layer 136.

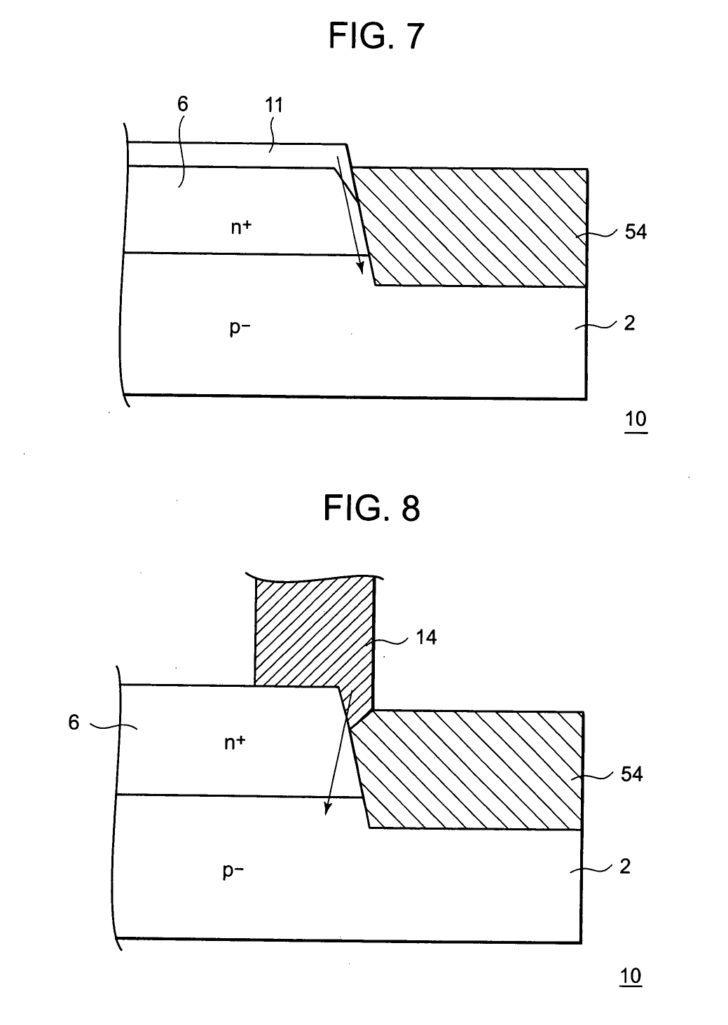

In this embodiment, since the surface height of the second STI film 154b in the DRAM part is higher than the surface height of the semiconductor substrate 102, the corner of the impurity diffusion layer 106 can be made so as not to be exposed at the part connected to the second STI film 154b when the surface of the second STI film 154b is scraped by being etched after formation of the second STI film 154b. As a result, it is possible to prevent junction leak as explained in FIGS. 7 and 8 from being created. Herein, in the step for forming the contact 114 over the impurity diffusion layer 106 after forming the second STI film 154b, the surface height of the second STI film 154b is made to be higher than the semiconductor substrate 102 to the extent to which the corner of the impurity diffusion layer 106 is not exposed at the part in contact with the second STI film 154b even if the second STI film 154b is scraped by being etched. For instance, when the second STI film 154b is formed, the surface height of the second STI film 154b can be made, for instance, 10 nm to 20 nm higher than the surface height of the semiconductor substrate 102.

Moreover, in this embodiment, the machining accuracy of the element in the Logic part can be maintained well because the surface of the semiconductor substrate in the Logic part can be made flat.

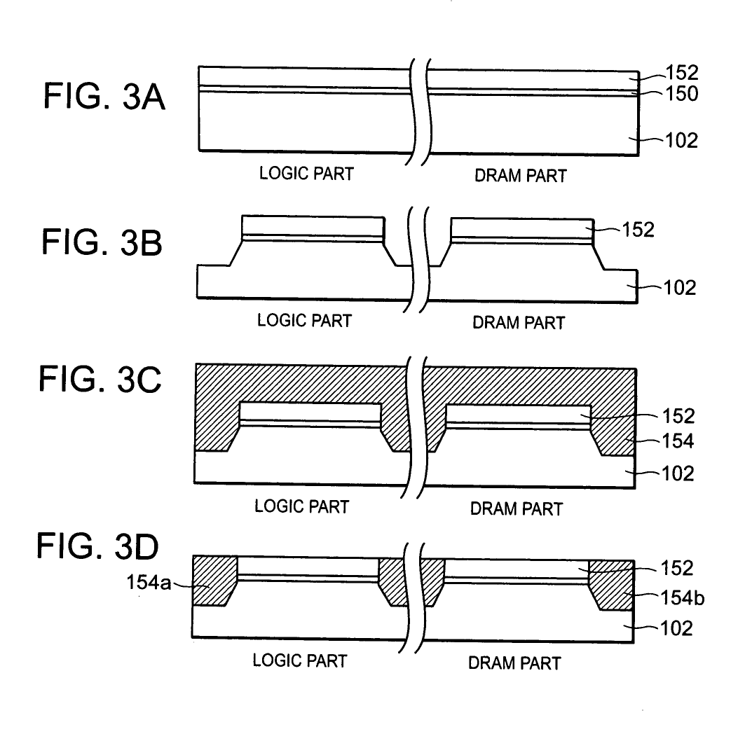

Next, the manufacturing procedure of the semiconductor device 100 in this embodiment will be explained. FIGS. 3 to 5 are process cross-sectional drawings illustrating a manufacturing procedure of the semiconductor device 100.

First of all, a thermally oxidized film 150 and a silicon nitride film 152 (a first mask layer) are formed over the entire surface of the semiconductor substrate 102 (FIG. 3A). The film thickness of the silicon nitride film 152 is controlled to be, for instance, 100 nm.

Next, in order to form the isolation region in the semiconductor substrate 102, a concave part is formed in the silicon nitride film 152 and the semiconductor substrate 102 by etching (FIG. 3B). Next, an STI film 154 is formed by a CVD (Chemical Vapor Deposition) technique over the entire surface of the semiconductor substrate 102 (FIG. 3C). A silicon oxide film can be used for the STI film 154. Moreover, before forming the STI film 154, a liner film may be formed over the bottom and sides of the aforementioned concave part by forming a silicon nitride film over the entire surface of the semiconductor substrate 102 by a CVD technique.

Then, the STI film 154 which is exposed outside of the concave part over the silicon nitride film 152 is removed by a CMP (Chemical Mechanical Polish) technique (FIG. 3D). As a result, the second STI film (isolation dielectric film) 154b and the first STI film 154a are formed over the DRAM part and a Logic part, respectively.

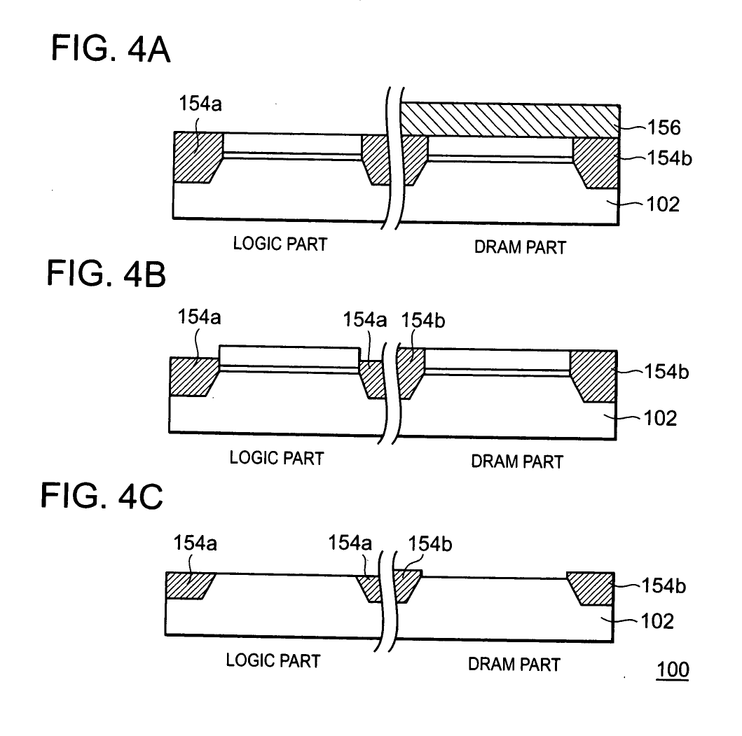

Next, a resist film 156 (second mask layer) is selectively formed over the DRAM part (FIG. 4A). After forming the resist film 156 over the entire surface of the semiconductor substrate 102, it is selectively formed over the DRAM part by removing the resist film 156 formed over the Logic part. FIG. 6 is a top view illustrating a configuration of the semiconductor device 100. Herein, the Logic part is formed around the DRAM part. In the step shown in FIG. 4A, the resist film 156 is removed so that the resist film 156 selectively remains in the DRAM part.

Back to FIG. 4, by wet-etching using the resist film 156 as a mask, the upper part of the first STI film 154a in the Logic part is partially removed. In this step, hydrofluoric acid and buffered hydrofluoric acid, etc. can be used as an etchant. As a result, the surface height of the first STI film 154a in the Logic part becomes lower than the surface height of the second STI film 154b in the DRAM part (FIG. 4B).

After that, the resist film 156 is removed. Then, the upper parts of the first STI film 154a and the second STI film 154b are partially removed by wet-etching the entire surface of the semiconductor substrate 102.

Next, the silicon nitride film 152 and the thermally oxidized film 150 are removed by etching (FIG. 4C). The upper parts of the first STI film 154a and the second STI film 154b are slightly etched during this etching, so that the surface height of the first STI film 154a becomes almost equal to the surface height of the semiconductor substrate 102 in the Logic part. On the other hand, the state where the surface height of the second STI film 154b is higher than the surface height of the semiconductor substrate 102 is maintained in the DRAM part.

Then, a silicon oxide film is formed over the semiconductor substrate 102 by heat-treatment. Next, a polysilicon film is formed over the silicon oxide film by a CVD technique. By using a well-known lithography technique, the polysilicon film and the silicon oxide film are patterned, in order, to be the shape of the gate electrode. As a result, a gate 110 is formed, which consists of the gate insulation film composed of the silicon oxide film and the gate electrode composed of the polysilicon film. As a material of the gate insulation film, a high permittivity film and a multilayer film of a silicon oxide film and a high permittivity film may be used. Moreover, the gate electrode may be assumed to be a metal gate.

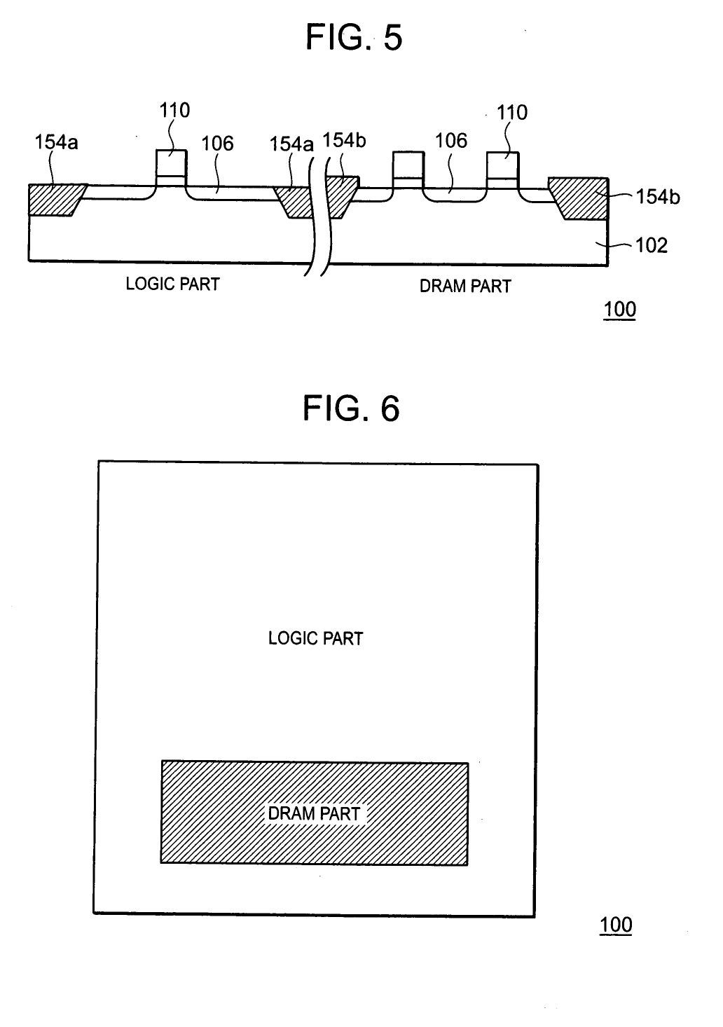

Nest, ion implantation is performed on the semiconductor substrate 102 using the gate 110 as a mask for forming the impurity diffusion layer 106 (FIG. 5). The impurity diffusion layer 106 becomes a source or a drain of a MOS transistor. A sidewall, etc. may be formed as appropriate by a well-known gate formation procedure after forming the gate 110. Moreover, the impurity diffusion layer 106 may be formed together with the gate 110 by using the sidewall as a mask, and the sidewall is formed after forming the impurity diffusion layer 106 to form a MOS transistor having an LDD (lightly doped drain) structure.

After that, a metallic film is formed over the entire surface of the semiconductor substrate 102. In this embodiment, the metallic film is composed of nickel and cobalt. The metallic film can be formed by a sputtering technique. Then, the metallic film and silicon in contact with the metallic film are reacted by heat-treatment to form a silicide film 111. When the gate electrode of the gate 110 is formed of polysilicon, a silicide layer can be formed also over the gate electrode. Next, an unreacted metallic film is removed therefrom. The silicide film 111 may be, for instance, NiSi and CoSi. The manufacturing process of a MOS transistor described above shows one example and a MOS transistor can be manufactured with other various configurations and by using other processes.

According to the treatment described above, the surface height of the semiconductor substrate 102 can be made almost equal to the surface height of the first STI film 154a and the surface height of the second STI film 154b can be made higher than the surface height of the semiconductor substrate 102. Moreover, the surface height of the semiconductor substrate 102 in the Logic part is equal to the surface height of the semiconductor substrate 102 in the DRAM part. As a result, the semiconductor device 100 shown in FIG. 1 is formed. Although the surface height of the first STI film 154a is made almost equal to the surface height of the semiconductor substrate 102, it is not necessary to make the surface height of the first STI film 154a equal to the surface height of the semiconductor substrate 102. It is enough that the difference between the surface height of the first STI film 154a and the surface height of the semiconductor substrate 102 be made smaller than the difference between the surface height of the second STI film 154b and the surface height of the semiconductor substrate 102. In the selective etching of the upper part of the first STI film 154a in the aforementioned Logic part, the difference between the surface height of the first STI film 154a and the surface height of the semiconductor substrate 102 can be made smaller than the difference between the surface height of the second STI film 154b and the surface height of the semiconductor substrate 102 by controlling the amount of etching.

Then, the interlayer dielectric film 108 is formed over the entire surface of the semiconductor substrate 102. A contact hole is formed in the interlayer dielectric film 108 to reach the impurity diffusion layer 106 and the contact hole is filled with the barrier metal film 112 and the metallic film 113. Herein, the barrier metal film 112 is, for instance, composed of a TiN film, etc. and the metallic film 113 is, for instance, composed of a W film, etc. Then, the metallic film 113 and the barrier metal film 112 exposed outside of the contact hole over the interlayer dielectric film 108 is removed by a CMP technique, resulting in the contact 114 being formed. After that, the etching inhibition film 116 and the interlayer dielectric film 118 are formed over the entire surface of the semiconductor substrate 102.

Next, in the DRAM part, a concave part is formed in the interlayer dielectric film 118 and the etching inhibition film 116 in order to make a capacitor 126. Then, the concave part is filled with the lower electrode 120, the capacitive film 122, and the upper layer electrode 124. As a result, the capacitor 126 is formed. After this, an interlayer dielectric film 130 is formed over the entire surface of the semiconductor substrate 102. A contact hole which reaches the contact 114 is formed in the interlayer dielectric film 130, the interlayer dielectric film 118, and the etching inhibition film 116, and the inside of this contact hole is filled with a barrier metal film 132 and a metallic film 133. Next, the metallic film 133 and the barrier metal film 132 exposed outside of the contact hole is removed by a CMP technique, resulting in the contact 134 being formed. After that, an interconnection layer 136 is formed over the interlayer dielectric film 130. As a result, a semiconductor device 100 having the configuration shown in FIG. 2 is formed. The manufacturing process of a capacitor described above shows one example and a capacitor can be manufactured in other various configurations and by using other processes.

According to a semiconductor device 100 of this embodiment, the machining accuracy of the element in the Logic part can be maintained well and junction leakage can be prevented at the second STI film 154b of the DRAM part in the memory region.

Up to this point, embodiments of the present invention have been explained referring to the figures. However, it is apparent that the present invention is not limited to the above embodiments, but may be modified and changed without departing from the scope and spirit of the invention.

What is claimed is:

1. A semiconductor device comprising:
a semiconductor substrate in which a memory region and a logic region are embedded;
a first isolation dielectric film formed in said logic region of said semiconductor substrate; and
a second isolation dielectric film formed in said memory region of said semiconductor substrate, the surface height thereof being higher than the surface height of said semiconductor substrate,
wherein the surface height of said semiconductor substrate in said logic region and the surface height of said semiconductor substrate in said memory region are almost equal; and
the difference between the surface height of said first isolation dielectric film and the surface height of said semiconductor substrate is smaller than the difference between the surface height of said second isolation dielectric film and the surface height of said semiconductor substrate.

2. The semiconductor device according to claim 1,
wherein the surface height of said first isolation dielectric film is almost equal to the surface height of said semiconductor substrate.

3. The semiconductor device according to claim 1, further comprising:
an impurity diffusion region formed in a region adjacent to said second isolation dielectric film of the surface part of said semiconductor substrate in said memory region; and
a silicide layer formed over said impurity diffusion region in said memory region.

4. The semiconductor device according to claim 1, further comprising:
an impurity diffusion region formed in a region adjacent to said second isolation dielectric film of the surface part of said semiconductor substrate in said memory region;
a contact provided over said semiconductor substrate and electrically connected to said impurity diffusion region in said memory region; and
a capacitor provided over said semiconductor substrate and connected to said contact in said memory region.

5. The semiconductor device according to claim 4,
wherein a silicide layer formed over said impurity diffusion region is included in said memory region, and
said contact is provided making contact with said silicide layer and connected to said impurity diffusion region through said silicide layer.

6. A manufacturing method of a semiconductor device comprising the steps of:
forming a first mask layer over the entire surface of a semiconductor substrate where a memory region and a logic region are embedded;
forming a concave part in said first mask layer and said semiconductor substrate to form an isolation region in said semiconductor substrate in said memory region and said logic region;
forming an insulation film over the entire surface of said semiconductor substrate to bury said concave part with said insulation film;
removing said insulation film exposing the outside of said concave part of said first mask layer and forming a first isolation dielectric film and a second isolation dielectric film in said logic region and said memory region, respectively;
forming a second mask layer selectively over said memory region;
removing the upper part of said first isolation dielectric film partially by using said second mask layer as a mask;
removing said second mask layer; and
removing said first mask layer,
wherein the surface height of said first isolation dielectric film is made almost equal to the surface height of said semiconductor substrate and the surface height of said second isolation dielectric film is made higher than the surface height of said semiconductor substrate.

7. A semiconductor device comprising:
a semiconductor substrate including first and second regions, surfaces of said first and second regions being the substantially same in height as each other;
a first isolation film selectively formed in said first region; and
a second isolation film selectively formed in said second region,
said first isolation film protruding from the surface of said first region larger than said second isolation film.

8. The semiconductor device according to claim 7,
wherein said first region is provided for a memory circuit having a plurality of first transistors and said second region is provided for a logic circuit having a plurality of second transistors.

9. The semiconductor device according to claim 8,
wherein said first isolation film is provided to define a plurality of first element formation regions for said first transistors and said second isolation film is provided to define a plurality of second element formation regions for said second transistors.
